(19) United States
(12) Patent Application Publication
(10) Pub. No.: US 2009/0230438 A1
(43) Pub. Date: Sep. 17, 2009

(54) SELECTIVE NITRIDATION OF TRENCH ISOLATION SIDEWALL

(75) Inventors: Zhijiong Luo, Carmel, NY (US); Huilong Zhu, Poughkeepsie, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 12/047,821

(22) Filed: Mar. 13, 2008

(51) Int. Cl. H01L 29/00; H01L 21/76

(52) U.S. Cl. 257/288; 438/425; 257/E21.54; 257/E29.001

(57) ABSTRACT

A method is provided of forming a trench isolation region adjacent to a single-crystal semiconductor region for a transistor. Such method can include, for example, recessing a single-crystal semiconductor region to define a first wall of the semiconductor region, a second wall remote from the first wall and a plurality of third walls extending between the first and second walls, each of the first and second walls extending in a first direction. In one embodiment, the first direction may be a <110> crystallographic direction of a wafer such as a silicon direction, for example. Oxidation-inhibiting regions can be formed at the first and second walls of the semiconductor region selectively with respect to the third walls. A dielectric region can then be formed adjacent to the first, second and third walls of the semiconductor region for a trench isolation region. During the formation of the dielectric region, the oxidation-inhibiting regions reduce oxidation of the semiconductor region at the first and second walls relative to the plurality of third walls. A transistor formed in the semiconductor region can have a channel whose length is oriented in the first direction by processing including annealing, which at least partially oxidizes the semiconductor region at the third walls.

### BACKGROUND OF THE INVENTION

The present invention relates to the fabrication of semiconductor devices, especially devices within semiconductor integrated circuits.

FIG. 1 is a plan view illustrating a structure of a semiconductor device such as a field effect transistor (“FET”) 10 according to the prior art. The FET can be a p-type FET (“PFET”) having a p-type conduction channel or an n-type FET (“NFET”) having an n-type conduction channel. As illustrated in FIG. 1, the FET includes an active semiconductor region 12 having walls 24, 26 surrounded by a trench isolation region such as a shallow trench isolation (“STI”) region, for example. The active semiconductor region may consist essentially of a single-crystal semiconductor such as silicon, for example, or may include a single-crystal alloy of silicon with another semiconductor, such as silicon germanium or silicon carbon, for example. One or more dopant materials may be incorporated into the single-crystal semiconductor region such as boron, phosphorus or arsenic, for example. A gate conductor 16, which may include or consist essentially of a polycrystalline semiconductor such as polysilicon, overlies the active semiconductor region and extends in a direction of a width 18 of a channel of the FET. First and second spacers 20, 22, respectively, are illustrated at edges of the gate conductor 16.

During the fabrication of the FET, walls 24 and walls 26 of the active semiconductor region 12 may become oxidized, in that some of the semiconductor material at the walls is consumed and forms an oxide. Oxidation that occurs during or after the filling of the STI regions can cause volume expansion at the walls 24, 26 which oxidation can exert a compressive stress upon the semiconductor region. When the walls 24 become oxidized, a compressive stress is exerted on the semiconductor region 12 in a first direction through line Y-Y′. When the walls 26 become oxidized, a compressive stress is exerted on the semiconductor region 12 in a second direction through line X-X′. When the FET is a PFET, compressive stress in the X-X′ direction can benefit the performance of the PFET. Such compressive stress can add to compressive stress applied by other means to increase the performance of the PFET. However, typically compressive stress in the Y-Y′ direction of the semiconductor region does not benefit the performance of the FET, regardless of whether the transistor is an NFET or a PFET. Instead, a compressive stress in Y-Y′ direction can degrade the transistor's performance. The X-X′ direction is the direction in which electrons or holes flow in the channel of the FET, which normally is aligned with a <110> crystallographic direction of a silicon wafer having an <100> orientation.

### SUMMARY OF THE INVENTION

Accordingly, the inventors have recognized that the oxidation of the semiconductor region at walls 24 during fabrication of the FET should be reduced or eliminated to avoid degrading the performance of the FET. Further, by reducing the oxidation of the semiconductor region at walls 24 selectively relative to walls 26, the unwelcome compressive stress in the Y-Y′ direction can be reduced selectively relative to that applied in the X-X′ direction.

Thus, in accordance with an aspect of the invention, A method is provided of forming a trench isolation region adjacent to a single-crystal semiconductor region for a transistor. Such method can include, for example, recessing a single-crystal semiconductor region to define a first wall of the semiconductor region, a second wall remote from the first wall and a plurality of third walls extending between the first and second walls, each of the first and second walls extending in a first direction. In one embodiment, the first direction may be a <110> crystallographic direction of a wafer such as a silicon wafer, for example. Oxidation-inhibiting regions can be formed at the first and second walls of the semiconductor region selectively with respect to the third walls. A dielectric region can then be formed adjacent to the first, second and plurality of third walls of the semiconductor region for a trench isolation region. During the formation of the dielectric region, the oxidation-inhibiting layers reduce oxidation of the semiconductor region at the first and second walls relative to the third walls. A transistor formed in the semiconductor region can have a channel whose length is oriented in the first direction by processing including annealing, which may at least partially oxidize the semiconductor region at the third walls.

In accordance with another aspect of the invention, a semiconductor device is provided. The semiconductor device can include a single-crystal semiconductor region having a first wall, a second wall remote from the first wall and a plurality of third walls extending between the first and second walls. In one embodiment, each of the first and second walls can extend in a first direction and a transistor can be disposed in the semiconductor region, the transistor having a channel whose length is in the first direction. The first direction may be a <110> crystallographic direction of a wafer such as a silicon wafer, for example. A dielectric region can be disposed adjacent to the first, second and the purality of third walls of the semiconductor region, such as for a trench isolation region. An oxide layer may be disposed between the semiconductor region and the dielectric region at the walls of the semiconductor region. An oxidation-inhibiting first layer having a first composition may be disposed along the first and second walls of the semiconductor region, causing the thickness of the oxide layer to be reduced where the first layer is present.

### BRIEF DESCRIPTION OF THE DRAWINGS

FIG. 1 is a top-down plan view illustrating a field effect transistor (“FET”) in accordance with the prior art.

FIG. 2 is a top-down plan view illustrating a field effect transistor (“FET”) in accordance with an embodiment of the invention.

FIG. 3 is a sectional view corresponding to the plan view of the field effect transistor illustrated in FIG. 2 through line X-X′.

FIG. 4 is a sectional view corresponding to the plan view of the field effect transistor illustrated in FIG. 2 through line Y-Y′.

FIGS. 5 through 10 are various views illustrating stages in fabrication to form a FET 110 (FIGS. 2 through 4) in accordance with an embodiment of the invention.

### DETAILED DESCRIPTION

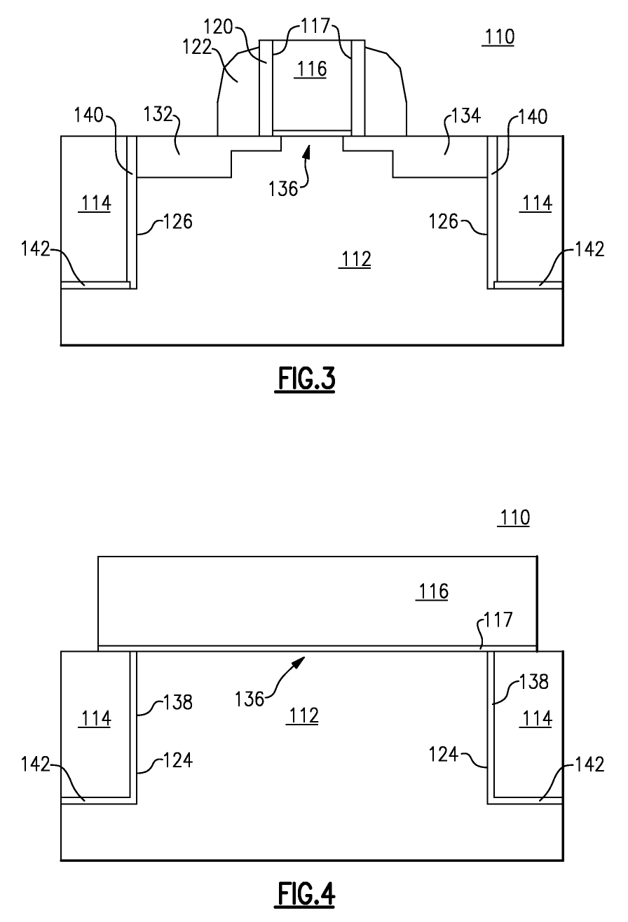

FIG. 2 is a top-down plan view illustrating a FET in accordance with an embodiment of the invention. The FET has a single-crystal active semiconductor region 112 extending from a wall 126 to another wall 126 remote therefrom. The active semiconductor region may include a semiconductor such as silicon or a semiconductor alloy, such as silicon germanium or silicon carbon, for example. In one embodiment, the semiconductor may include a compound semiconductor such as gallium arsenide (GaAs) or other III-V compound of a Group III element with a Group V element of the periodic table of elements. In one embodiment, the semiconductor may include a compound semiconductor such as a II-VI compound of a Group II element with a Group VI element of the periodic table of elements.

The FET can include a source region 132 and a drain region 134 separated from the source region by a channel 136. A gate conductor 116 extends between walls 124 across an entire width of the semiconductor region in a direction aligned with a width 118 of the channel 136. The gate conductor may include conductive or semiconductive regions and may include one or more of a semiconductor material, a metal or a compound of a metal with a semiconductor material. First spacers 120 adjacent to walls 117 of the gate conductor 116 can have small thickness, as illustrated in FIG. 2. Spacers 120 may be formed, for example, by oxidation of semiconductor material present at walls of the gate conductor 116. Alternatively, spacers 120 may be formed by depositing a conformal layer of dielectric material and performing anisotropic etching, e.g., a reaction ion etch. Second spacers 122 may be provided which are adjacent to the first spacers and farther away from walls 117 of the gate conductor, such as by the aforementioned deposition and reactive ion etching techniques, for example.

When the semiconductor region 112 is part of a silicon wafer, the semiconductor region and the wafer typically are in a <100> orientation. As depicted in FIG. 2, the semiconductor region 112 extends between the walls 124 in a direction of the width of the channel 136. The walls 124 of the semiconductor region typically are oriented in a direction of the length 130 of the channel but need not be entirely aligned with such direction. The length of the channel typically is aligned with a <110> crystallographic direction of the semiconductor region when the semiconductor region is in the <100> direction. The semiconductor region 112 extends between the walls 124 in a direction of the length of the channel. The walls 126 of the semiconductor region may be at right angles to the walls 124 and be oriented in a direction of the width 118 of a channel of the FET but need not be entirely aligned with a direction of the width 118 of the channel.

As further depicted in FIG. 2, a layer 138 having a first composition extends along walls 124 of the semiconductor region 112. Layer 140 having a second composition extends along the walls 126. The first composition layer and the second composition layer typically are disposed in contact with the semiconductor region 112. The first composition is such that, during fabrication of the FET, the first composition layer inhibits oxidation of the semiconductor region at the walls 124 relative to oxidation of the semiconductor region at the walls 126. In one embodiment, the first composition can include a nitrided oxide which operates to inhibit oxidation of the semiconductor region 112 at walls 124 of the semiconductor region. Such layer 138 may include an oxide such as silicon dioxide, for example, having a relatively high percentage of incorporated nitrogen. By contrast, the second composition of layer 140 may have much less incorporated nitrogen, or may not contain nitrogen. When there is a measurable quantity of incorporated nitrogen in the second layer 140, such quantity typically is multiple orders of magnitude less than the quantity of the incorporated nitrogen in the first layer 138. Due to the oxidation-inhibiting effect of layer 138, the thickness of any oxide layer which grows at walls 124 is reduced in relation to the thickness of the oxide layer 140 which grows along walls 126. In addition, the thickness of the layer 138 may be less than the thickness of layer 140.

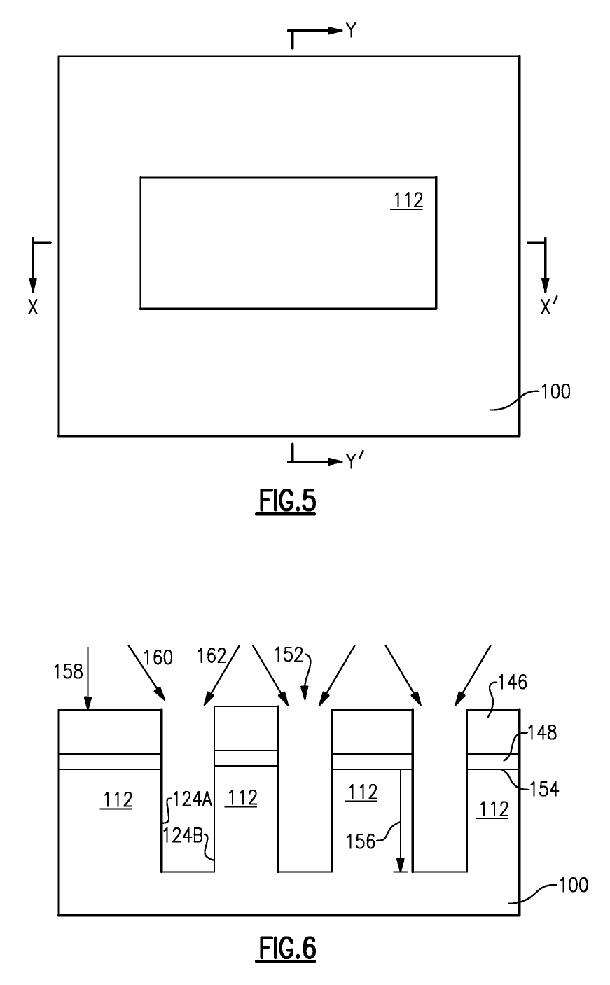

FIG. 3 is a sectional view through line X-X′ corresponding to plan view illustrated in FIG. 2 and which further illustrates the FET 10. The location of the active semiconductor region 112 between the oxide layer 140 at edges of STI region 114 is apparent in FIG. 3. The locations of the channel 136 underneath the gate conductor 116 of the FET and the source 132 and the drain 134 at opposite ends of the FET are further apparent in FIG. 3. A nitrided oxide layer 142 may further line bottom surfaces of the STI regions 114 adjacent to underlying semiconductor regions of the substrate. As illustrated in FIG. 3, the FET may further include a gate oxide 117, which separates the gate conductor 116 from the semiconductor region 112, first spacers 120 overlying walls 117 of the gate conductor and second spacers 122 overlying the first spacers 120.

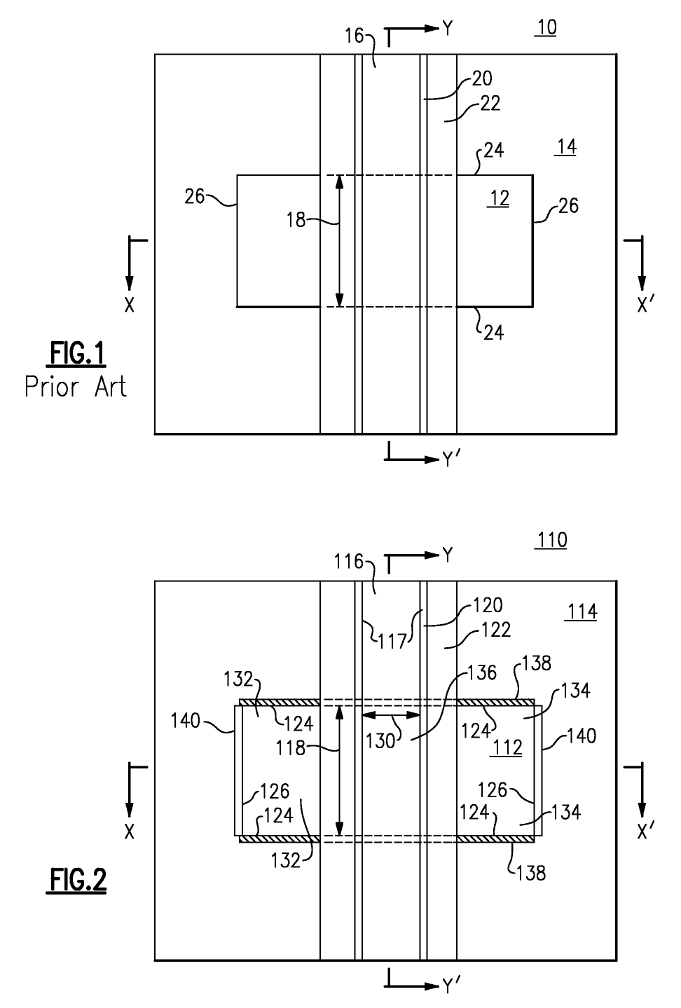

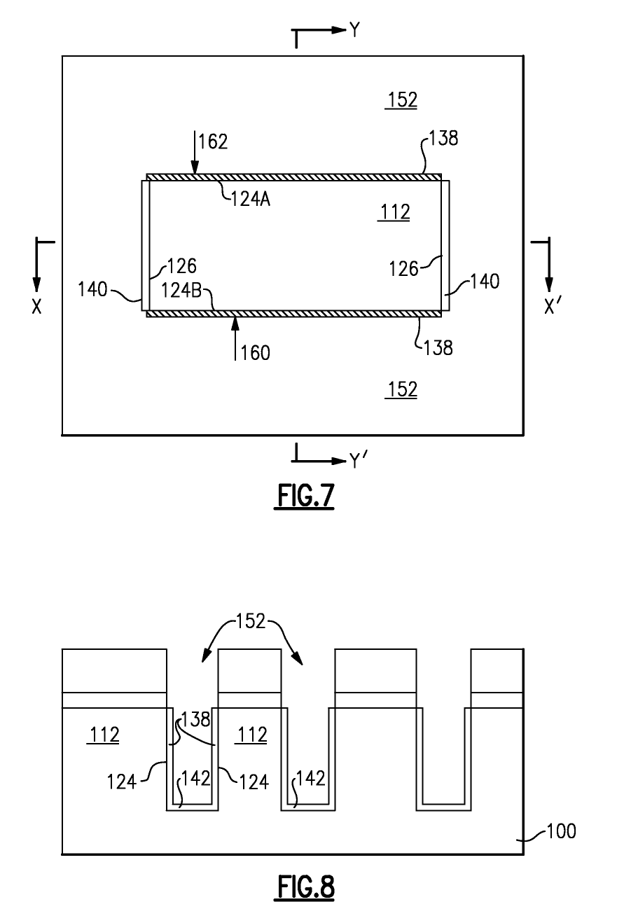

FIG. 4 is a corresponding sectional view through line Y-Y′ of FIG. 1. As illustrated therein, the active semiconductor region 112 and the channel 136 therein has walls 124 adjacent to the STI region 114. The oxide-inhibiting layer 138 lies between the active semiconductor region 112 and the STI region 114. The gate conductor 116 and gate oxide layer 117, which separates the gate conductor 116 from the semiconductor region 112, are also shown in FIG. 4. The nitrided oxide layer 142 is further illustrated in FIG. 4.

Due to their particular composition and thickness, layer 140 applies a compressive stress to the channel 136 of the FET in a direction aligned with line X-X′ (FIG. 2). When the FET is a PFET, such compressive stress, aligned in the direction of the length of the channel 136 benefits the performance of the FET. By contrast, layer 138, having smaller thickness and the fact that it inhibits oxidation of the semiconductor region 112, applies little compressive stress to the semiconductor region 112 relative to that applied by layer 140. As a result, the oxidation-inhibiting layer 138 reduces the magnitude of compressive stress applied to the channel region 136 in the Y-Y′ direction relative to the magnitude of compressive stress applied in the Y-Y′ direction to the channel region of the prior art FET 10 (FIG. 1).

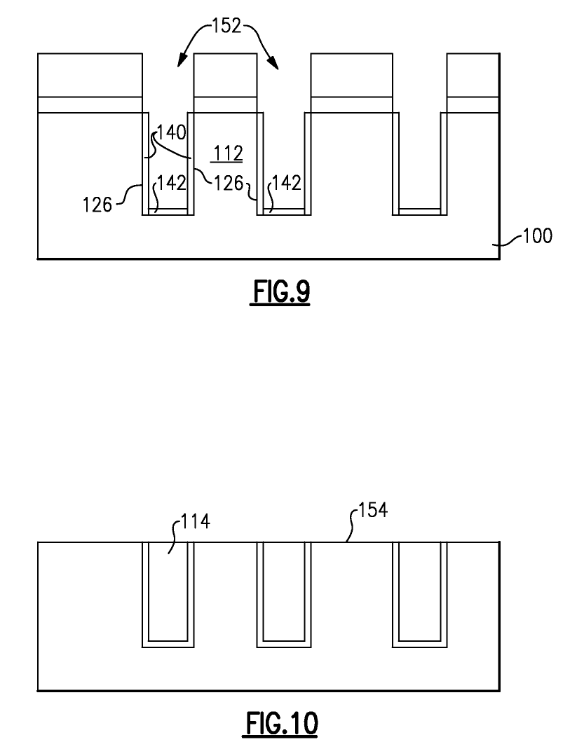

Referring to FIG. 5, a method will now be described for fabricating the FET illustrated in FIGS. 2 through 4. FIG. 5 is a top-down plan view illustrating a stage of fabrication in which the location and extent of the semiconductor region 112 are defined by patterning a semiconductor wafer 100 from a top surface thereof. For example, mask patterns can be formed by photolithographic processing, after which material can be removed from the wafer in locations not covered by the mask patterns. In a specific example, a hard mask can be formed to have a plurality of patterns each overlying a major surface of the wafer, such areas to become active semiconductor regions 112. Subsequently, a reaction ion etch can be used to remove portions of the semiconductor material adjacent to the major surface, thus etching downwardly from the major surface to a controlled depth, but leaving the active areas intact.

FIG. 6 is corresponding sectional view illustrating the same stage of fabrication, wherein the hard mask can include, for example, a pad nitride 146 and a pad oxide 148 between the pad nitride and the major surface 154 of the wafer 100. Alternatively, the hard mask can include a combination of the pad nitride, pad oxide and an additional hard mask layer such as an oxide dielectric layer (not shown) overlying each of the patterns of the pad nitride layer 146 shown in FIG. 6. Trenches 152 are formed which extend in a downward direction from the major surface 154 of the wafer to a uniform depth 156 below the major surface 154. After further processing, areas of the wafer between adjacent ones of the trenches will eventually become active semiconductor regions 112 of the wafer 100.

As further illustrated in FIG. 6, angled ion implantation is used to implant a species into the semiconductor regions 112 which aids the formation of oxidation inhibiting layers 138 (FIG. 2). Angled ion implantation is used in order to selectively implant the species only into the semiconductor regions at certain walls 124 of the trenches 152 but not others. In addition, the angled ion implantation is performed in one direction 160 at one angle with respect to a normal angle to the major surface 154 of the wafer and then is performed in another direction 162 at another angle with respect to the normal angle 158. In this way, the species is implanted into the semiconductor regions 112 adjacent to the walls 124A which lie on one side of the trenches 152. The species is also implanted into the semiconductor regions 112 adjacent to the walls 124B which lie on the sides of the trenches 152 opposite from walls 124A. In one example, the implanted species can include N+ (nitrogen ions) or N₂ (nitrogen molecules). Alternatively, in another example, the implanted species can include carbon. In another example, the implanted species can include nitrogen and carbon.

FIG. 7 is a corresponding top-down plan view further illustrating the directions in which the species are implanted through trenches 152 into the semiconductor region 112 at the walls 124A and 124B. Typically, no intentional implanting of the species is performed into the semiconductor region 112 adjacent to walls 126. Subsequent thereto, after implanting the species, the wafer undergoes thermal processing by which the oxidation-inhibiting layer 138 forms adjacent to walls 124A, 124B of the semiconductor region 112 and an oxide layer 140 forms adjacent to walls 126. For example, annealing at relatively high temperatures, e.g., above 700° C., can be performed at various points in processing which can lead to formation of the layers 138, 140. Alternatively, the layers 138, 140 can be formed by processing controlled in accordance with that specific purpose. When the implanted species is nitrogen, the resulting oxidation-inhibiting layer 138 can be a nitrided oxide layer, i.e., an oxide layer which contains a percentage of included nitride which is sufficient to produce the above-described oxidation-inhibiting effect. The concentration of the nitrogen species in the semiconductor region 112 adjacent to walls 124A and 124B determine to what extent the semiconductor region 112 becomes oxidized at those walls and how thick the layer 138 becomes. By contrast, the lack of the implanted species at walls 126 allows the oxide layer 140 adjacent to those walls to grow without being impeded by the implanted species during the annealing or other thermal processing steps performed at at least moderately high temperatures.

FIG. 8 is a corresponding sectional view of the wafer 100 through line Y-Y′ of FIG. 7 at this stage of fabrication, after formation of the oxidation-inhibiting (nitrided oxide) layers 138 along walls 124 of the semiconductor regions 112. FIG. 8 also illustrates the location of nitrided oxide layers 142 disposed along the bottoms of the trenches 152.

FIG. 9 is a corresponding sectional view of the wafer 100 through line X-X′ of FIG. 7, in which oxide layers 140 are shown disposed along walls 124 of the semiconductor regions 112, in addition to the nitrided oxide layers 142 disposed along the bottoms of the trenches 152.

FIG. 10 is a sectional view illustrating a stage of fabrication subsequent to the stage of fabrication illustrated in FIGS. 7 through 9. As shown therein, the trenches are now filled with a dielectric material to form shallow trench isolation (‘STI”) regions 114, as described above with respect to FIGS. 2 through 4. Such structure is obtained through processing including depositing a dielectric material into the trenches 152 (FIG. 8), e.g., an oxide of silicon, such as by high density plasma (“HDP’) or other technique. After filling the trenches, the hard mask patterns and portions of the deposited dielectric material which overlie the major surface 154 are removed, such as by various removal techniques, which may include chemical mechanical processing (“CMP”), for example.

Following the stage of fabrication illustrated in FIG. 10, further processing is performed to form particular structures in the active semiconductor region 112 (FIG. 2), e.g., the source and drain, and above the active semiconductor region, e.g., as the gate conductor and spacers to form the FET 110 (FIGS. 2 through 4).

While the invention has been described in accordance with certain preferred embodiments thereof, many modifications and enhancements can be made thereto without departing from the true scope and spirit of the invention, which is limited only by the claims appended below.

What is claimed is:

1. A method of forming a trench isolation region adjacent to a single-crystal semiconductor region for a transistor, the method comprising:
(a) recessing a single-crystal semiconductor region to define a first wall of the semiconductor region, a second wall remote from the first wall and a plurality of third walls extending between the first and second walls, each of the first and second walls extending in a first direction;
(b) forming oxidation-inhibiting regions at the first and second walls of the semiconductor region selectively with respect to the third walls;
(c) depositing a dielectric material adjacent to the first, second and third walls of the semiconductor region to form at least one trench isolation region; and
(d) forming a transistor in the semiconductor region having a channel whose length is oriented in the first direction by processing including annealing to at least partially oxidize the semiconductor region at the third walls, wherein the oxidation-inhibiting regions reduce oxidation of the semiconductor region at the first and second walls relative to the third walls.

2. The method as claimed in claim 1, wherein the single-crystal semiconductor region is a region of a semiconductor wafer having a <100> crystal orientation and the first direction is a <110> crystallographic direction of the single-crystal semiconductor region.

3. The method as claimed in claim 2, wherein the at least partial oxidation of the semiconductor region applies a compressive stress to the semiconductor region at the third walls.

4. The method as claimed in claim 3, wherein the oxidation-inhibiting layers inhibit the application of a compressive stress to the semiconductor region in a direction between the first and second walls.

5. The method as claimed in claim 4, wherein step (d) includes growing a thermal oxide layer at the first, second and third walls, wherein the growth of the thermal oxide layer is controlled at the first and second walls in relation to the third walls by a concentration of the oxidation-inhibiting species in the oxidation-inhibiting regions.

6. The method as claimed in claim 1, wherein the oxidation-inhibiting regions are formed by implanting a species selectively into the semiconductor region at the first and second walls with respect to the semiconductor region at the third walls.

7. The method as claimed in claim 6, wherein the species is implanted into the semiconductor region at the first and second walls at angles with respect to a normal to a major surface of the semiconductor region.

8. The method as claimed in claim 7, wherein the species includes nitrogen.

9. A semiconductor device, comprising:
a single-crystal semiconductor region having a first wall, a second wall remote from the first wall and a plurality of third walls extending between the first and second walls, each of the first and second walls extending in a first direction;
a transistor having a channel disposed in the semiconductor region, the channel having a length extending in the first direction;
a dielectric region disposed adjacent to the first, second and third walls of the semiconductor region, the dielectric region formed as at least part of a trench isolation region;
an oxide layer disposed between the semiconductor region and the dielectric region at the walls of the semiconductor region; and
a first layer having a first composition overlying the first and second walls of the semiconductor region, the first layer inhibiting oxidation of the semiconductor region such that a thickness of the oxide layer is reduced where the first layer is present.

10. The semiconductor device as claimed in claim 9, wherein the single-crystal semiconductor region is a region of a semiconductor wafer having a <100> crystal orientation and the first direction is a <110> crystallographic direction of the single-crystal semiconductor region.

11. The semiconductor device as claimed in claim 10, wherein the second layer applies compressive stress to the semiconductor region at the third walls.

12. The semiconductor device as claimed in claim 11, wherein an amount of stress applied to the transistor channel in a direction of width of the transistor channel is lower than an amount of stress applied in the direction of the length of the transistor channel.

13. The semiconductor device as claimed in claim 10, wherein the first layers include thermally formed compounds of the implanted species with a semiconductor included in the semiconductor region.

14. The semiconductor device as claimed in claim 9, wherein the first layers include a compound of a species implanted into the semiconductor region adjacent to the first and second walls.

15. The semiconductor device as claimed in claim 14, wherein the implanted species is not present in the semiconductor region adjacent to the third walls.

16. The semiconductor device as claimed in claim 15, wherein the implanted species includes a species of nitrogen.

17. The semiconductor device as claimed in claim 16, wherein the first layer includes nitrided portions of the semiconductor region at the first and second walls.

18. The semiconductor device as claimed in claim 17, wherein the second layer includes oxidized portions of the semiconductor region at the third walls.
